(19) United States
(12) Patent Application Publication
(10) Pub. No.: US 2003/0231024 A1
(43) Pub. Date: Dec. 18, 2003

(54) Capacitive media resistivity, dialectic constant, and thickness sensor

(76) Inventor: Phillip R. Luque, Boise, ID (US)

Correspondence Address: HEWLETT-PACKARD COMPANY, Intellectual Property Administration, P.O. Box 272400, Fort Collins, CO, 80527-2400, US

(21) Appl. No.: 10/170,764

(22) Filed: Jun. 12, 2002

(51) Int. Cl. G01R 27/26

(52) U.S. Cl. 324/658

(57) ABSTRACT

This invention relates to a method and apparatus for measuring the resistivity, dialectic constant, and thickness of a media. Such structures of this type, generally, employ a pair of interdigital capacitive sensors that contact only one side of the media. An AC voltage is used to measure capacitance between the interdigital capacitive sensors. The capacitance readings from the sensors can be combined to compute the dialectic constant and the thickness of the media.

### FIELD OF THE INVENTION

This invention relates to a method and apparatus for measuring the resistivity, dialectic constant, and thickness of a media. Such structures of this type, generally, employ a pair of interdigital capacitive sensors that contact only one side of the media. An AC voltage is used to measure capacitance between the interdigital capacitive sensors. The capacitance readings from the sensors can be combined to compute the dialectic constant and the thickness of the media.

### DESCRIPTION OF THE RELATED ART

Prior to the present invention, as set forth in general terms above and more specifically below, it is known to employ a media resistivity measurement that applies a DC voltage to a conductive roller that touches one surface of the media and measures the DC current flowing to a conductive surface on the other side of the media sheet. While this system is capable of measuring the media resistivity, it requires the measurement of very small (<<1 μA) DC currents in an electrically noisy environment. Also, this method requires that the paper be fed through a small nip that adds mechanical complexity and cost, as well as making the media-handling device more subject to jamming. Also, it is well known that the bulk resistivity of a media with low surface resistivity cannot be accurately measured due to stray currents that flow across the media sheet and through other media handling device structures. Also, this method only measures the resistivity of the media. Finally, the sensor in this method makes poor contact with rough papers, thereby giving false high resistivity readings. Therefore, a more advantageous system would be one that would economically, accurately, and efficiently measure the resistivity and other characteristics of the media and adapt to the roughness of the media.

It is also known, in the media identification art, to employ a variety of methods to identify the media. Exemplary of such prior art are commonly assigned U.S. Pat. No. 6,047,110 ('110) to J. C. Smith, entitled “Method and Apparatus for Identifying a Print Media Type” and commonly assigned U.S. Pat. No. 6,291,829 ('829) to R. R. Allen et al., entitled “Identification of Recording Medium in a Printer.” The '110 and '829 references describe systems where combinations of LEDs and photodetectors are placed on one side or both sides of the media and various combinations of reflected and transmitted light are measured. Different media types will have distinctive “signatures” or combinations of light levels. By comparing the “signature” of the media in question with a set of known media, the media in the media-handling device can be identified. While these systems have met with a modicum of success, these systems measure properties that have no direct relation to the properties in question. Also, these systems require prior characterization of possibly a large number of media. Finally, these systems may have difficulty in recognizing environmental effects on media properties, such as the moisture sensitivity of the media. Therefore, a further advantageous system would be one that was also able to measure the actual characteristics of the media while recognizing any environmental effects on the media.

It is further known, in the media sensing art, to employ a variety of methods to determine the media quantity and media type. Exemplary of such prior art is commonly assigned U.S. Pat. No. 6,157,791 ('791) to R. E. Haines et al., entitled “Sensing Media Parameters.” The '791 reference describes a system where electrodes are placed on either side of the media and the AC impedance of the resulting capacitor is measured at a number of different frequencies. Different media types will have a distinctive “signature” or combinations of capacitance and loss (dissipation factor) at these frequencies. By comparing the “signature” of the media in question with a set of known media, the media in the media-handling device can be identified. While this system has also met with a modicum of success, this system requires that the media be fed through a small nap that adds mechanical complexity and cost, as well as making the media-handling device more subject to jamming. Also, the system does not directly measure the thickness or dielectric constant of the media, but rather a factor called dielectric thickness that is the dielectric constant divided by the thickness. Also, the system requires prior characterization of possibly a large number of media and does not address the problem of how new media types can be accommodated. Finally, the system may have difficulty in recognizing environmental effects on media properties. Therefore, a still further advantageous system would be one that would economically, accurately, and efficiently measure the resistivity and other characteristics of the actual media while recognizing any environmental effects on the media.

Finally, it is still further known, to employ a technique referred to as “Interdigital Electrode Dielectrometry.” A measurement device employs a set of interdigital electrodes using thin film techniques and is used to measure, for example, the dielectric properties of paper through the use of electrodes on each side of the paper, properties of bulk insulating liquids such as transformer oil where the sensor is immersed in the oil, and the properties of the vapor deposited thin film layers applied directly to the sensor. While these systems can measure a variety of material properties, they did not measure the properties of the media sheet placed on the sensor and do not utilize two sensors of different pitches to measure both the thickness and the electrical properties of the media sheet without any prior knowledge of these properties of the media sheet. Also, these systems do not use a thin insulating layer on the interdigital sensor to separate the sensor from the media.

It is apparent from the above that there exists a need in the art for a system which would economically, accurately, and efficiently measure the resistivity and other characteristics of the actual media, while adjusting to any roughness and environmental effects on the media, but which at the same time employed two sensors of different pitches to measure the thickness and the electrical properties of the media. It is a purpose of this invention to fulfill this and other needs in the art in a manner more apparent to the skilled artisan once given the following disclosure.

### SUMMARY OF THE INVENTION

Generally speaking, this invention fulfills these needs by providing a method for measuring/determining the capacitance, dielectric constant and thickness of a media, wherein the method is comprised of the steps of: exposing the one side of a media to a pair of interdigital capacitive sensors; applying an AC voltage across the sensors; measuring a capacitance on each of the sensors; determining a dielectric constant of the media from the capacitance; and determining a thickness of the media from the capacitance.

In certain preferred embodiments, the sensors include a thin layer of insulating material. Also, the sensors have different trace widths and gaps. The first sensor is built with small trace widths and gaps that are narrower than the typical thickness of a sheet of paper. The second sensor is built with wider traces and gaps, typically two to three times the trace and gap widths of the first sensor. Also, the capacitance readings from both sensors can be combined to compute the dielectric constant and the thickness of the media.

In general, each sensor can be characterized as yielding a capacitance reading that is a function of the media thickness and dialectic constant. The two functions are linearly independent so that they can be solved simultaneously to give a value for the media thickness and dielectric constant. In the media-handling device, this could be accomplished by generating a two-dimensional look-up table where each combination of two capacitance readings from the sensors gives a unique value of media dielectric constant and thickness.

In another further preferred embodiment, the bulk resistivity, dielectric constant, and thickness of the media are all measured simultaneously, accurately, and inexpensively. This allows for the media-handling device to accurately adjust to the thickness of the media without adversely affecting the operating characteristics of the media handling device.

The preferred media characteristic measurement method, according to this invention, offers the following advantages: lightness in weight; ease of assembly and repair; excellent media capacitance measurement characteristics; excellent media dielectric constant measurement characteristics; excellent media thickness measurement characteristics; ease of use; and excellent economy. In fact, in many of the preferred embodiments, these factors of lightness in weight, ease of assembly and repair, excellent media capacitance measurement characteristics, excellent media dielectric constant measurement characteristics, excellent media thickness measurement characteristics, ease-of-use, and economy are optimized to an extent that is considerably higher than heretofore achieved in prior, known media characteristic measurement methods.

The above and other features as invention, which will become more apparent as the description proceeds, are best understood by considering the following detailed description in conjunction with the accompanying drawings, wherein like characters represent like parts throughout the several views and in which:

### BRIEF DESCRIPTION OF THE DRAWINGS

FIG. 1 is a schematic illustration of an interdigital media sensor, according to one embodiment of the present invention;

FIG. 2 is another schematic illustration of the interdigital media sensor, according to another embodiment of the present invention;

FIG. 3 is a cross-sectional illustration of the interdigital media sensor of FIG. 2, taken along the line 3-3;

FIG. 4 is a schematic illustration showing the location of the interdigital media sensor in a media-handling device;

FIG. 5 illustrates a cross-section of a portion of a first sensor with contours showing the electric field;

FIG. 6 illustrates a cross-section of a portion of a second sensor with contours showing the electric field;

FIG. 7 is a graphical illustration of capacitance (in Farads) vs. paper thickness (in mils) for a 3 mil trace and gap;

FIG. 8 is a graphical illustration of capacitance (in Farads) vs. paper thickness (in mils) for a 10 mil trace and gap;

FIG. 9 is a graphical illustration of media volume resistivity (in Ohm-cm) vs. impedance phase angle (in degrees);

FIG. 10 is a block diagram of a circuit connected to the first sensor;

FIG. 11 is a block diagram illustrating how the AC signals representing the sensor voltage and current can be converted to digital signals by A/D converters and the microprocessor can calculate the amplitudes and phase of the signals;

FIG. 12 illustrates one preferred circuit for implementing the block diagram of FIG. 10;

FIG. 13 illustrates another preferred circuit for implementing the block diagram of FIG. 11;

FIG. 14 shows a circuit that can be used to convert a 1 kHz square wave into a sinusoidal signal;

FIG. 15 is a block diagram of a circuit connected to the first sensor, as in FIG. 10, utilizing an unbalanced approach;

FIG. 16 is a block diagram similar to FIG. 11 utilizing an unbalanced approach;

FIG. 17 illustrates one preferred circuit for implementing the block diagrams of FIGS. 15 and 16; and

FIGS. 18a-18d show four preferred oscillator circuits.

### DETAILED DESCRIPTION OF THE INVENTION

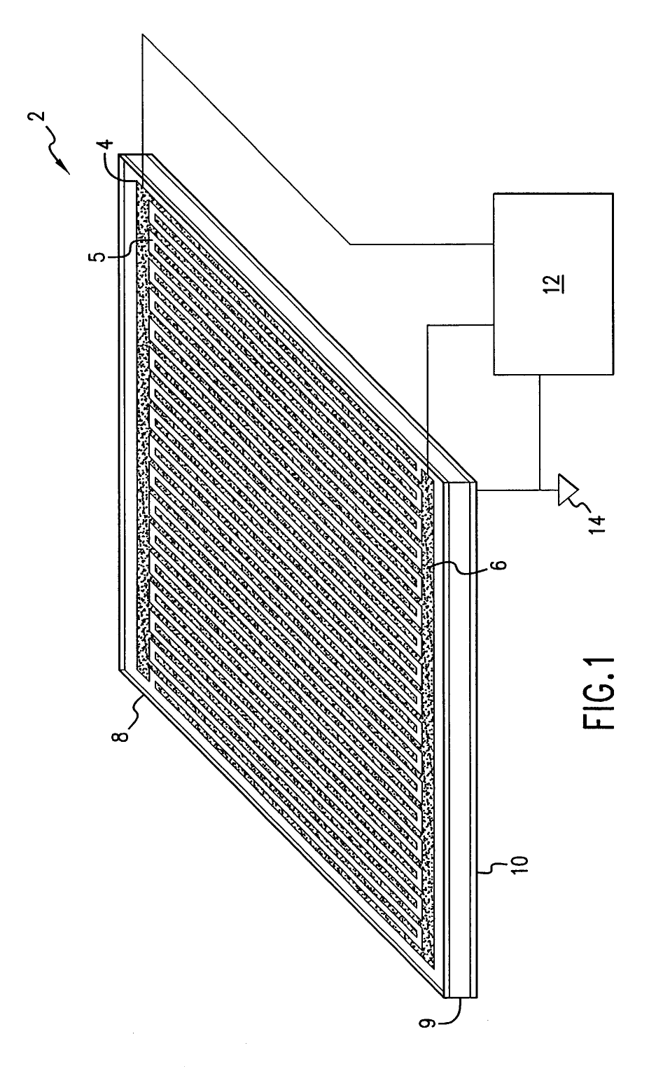

With reference first to FIG. 1, there is illustrated one preferred embodiment for use of the concepts of this invention. Interdigital media sensor 2 is shown in FIG. 1. Sensor 2 includes, in part, trace 4, gap 5, trace 6, surface insulating layer 8, ground plane insulating layer 9, ground plane 10, sensor circuit 12, and printer ground 14. As can be seen in FIG. 1, on top of sensor 2 an interdigital pattern is formed from a large number of parallel conductive traces 4, 6 having small gaps 5. Alternate traces 4, 6 are conventionally connected together at the ends by common leads that are connected to sensor circuits 12, preferably, located external to sensor 2. On the back of sensor 2 is a ground plane 10 separated from traces 4, 6 by layer of low dissipation factor insulating material 9, preferably, polyimide. Ground plane 10 is conventionally connected to printer ground 14 and sensor circuit 12. A thin layer of surface insulating material 8, preferably, polyimide, covers traces 4 and 6.

The present invention uses a pair of interdigital capacitive sensors 2 that contact only one side of the media. The two sensors 2 have different trace widths and gaps. The first sensor 2, preferably, is built with small trace widths and gaps that are narrower than the typical thickness of a sheet of paper. The second sensor 2, preferably, is built with wider traces and gaps, typically two to three times the trace and gap widths of the first sensor 2.

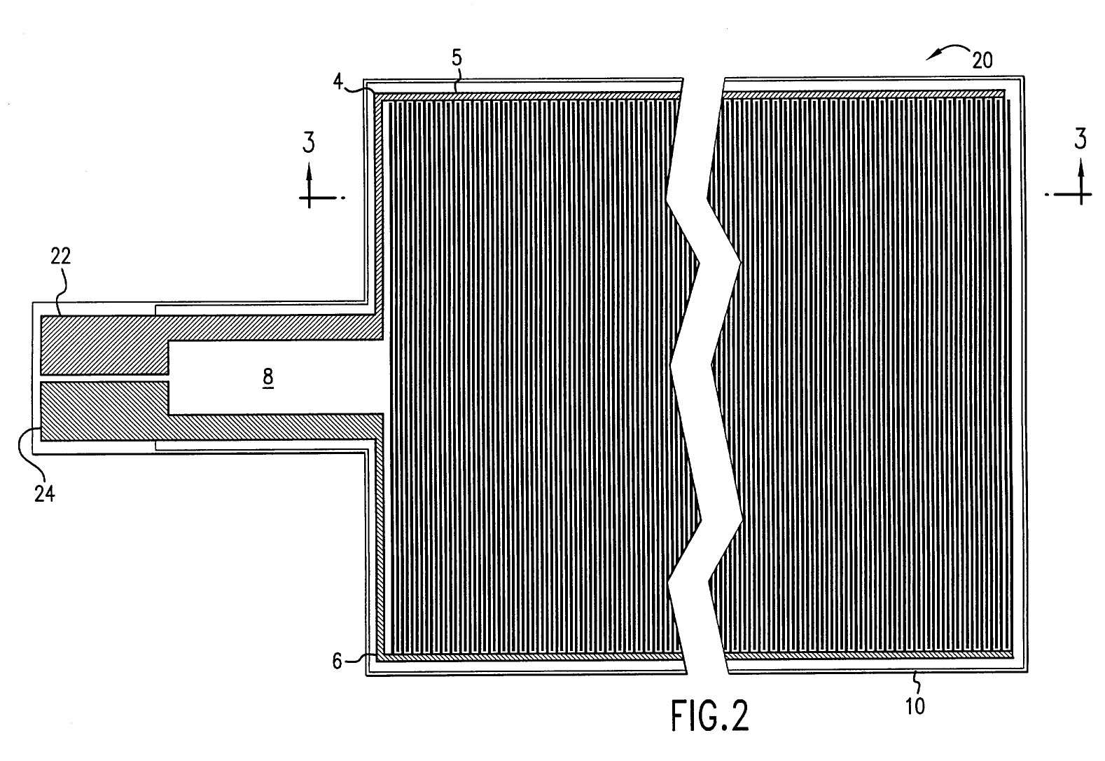

FIG. 2 illustrates interdigital capacitive sensor 20. Sensor 20 includes, in part, trace 4,gap 5, surface insulating layer 8, ground plane insulating layer (not shown), ground plane 10, and trace leads 22, 24. Sensor 20 is constructed in substantially the same manner as sensor 2 (FIG. 1). Trace leads 22 and 24 are conventionally connected to a sensor circuit (not shown), as discussed above with respect to sensor 2.

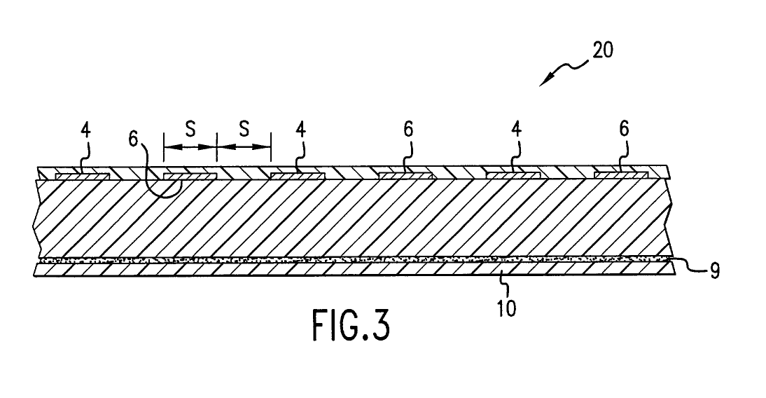

FIG. 3 is a cross-sectional illustration of interdigital capacitive sensor 20. As can be seen in FIG. 3, traces 4 and 6 are spaced apart from each other by a gap distance (S). The gap distance (S) can vary in from 0.003 inches to 0.010 inches depending upon if the first sensor 20 or a second sensor 20, as described above is utilized.

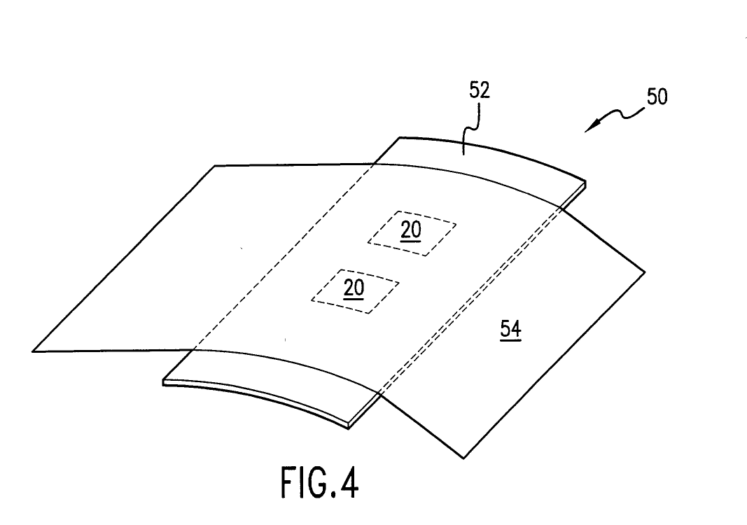

FIG. 4 illustrates how sensors 20 (or 2) are installed in the media-handling device. Preferably, sensors 20 are conventionally attached to a curved surface 52 in the media path of the media handling device so that as media 54, such as paper, moves through the media handling device, media 54 comes in contact with the surfaces of both sensors 20 (or 2). It is to be understood that traces 4 and 6 in each sensor 2 (or 20) form a capacitor. When media 54 is laid across the surface of sensor 20 (or 2), a portion of the electric field between traces 4 and 6 extends into media 54. Since media 54, typically, has a relative dielectric constant greater than unity, the capacitance between the alternate traces 4 and 6 is greater when media 54 is on sensor 20 than when no media is present.

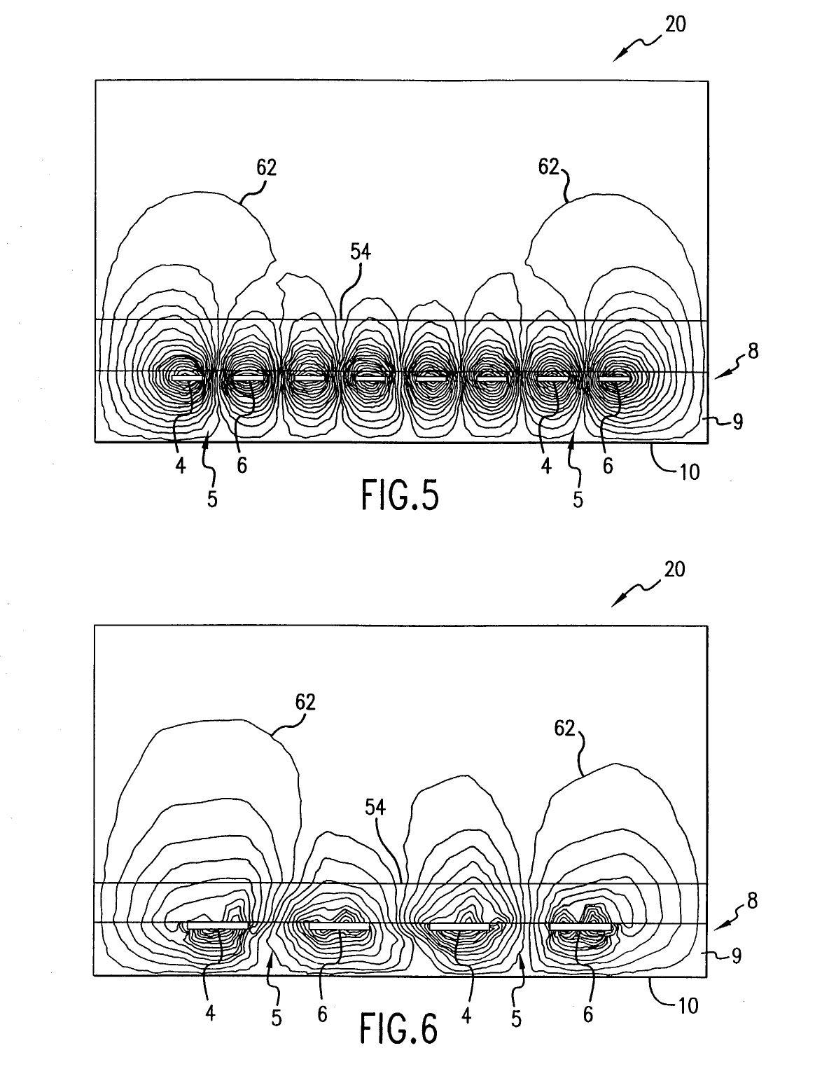

FIG. 5 shows a cross-section (similar to the cross-section in FIG. 3) of a portion of the first sensor 20 interacting with media 54 to create contours 62 showing the electric field. Preferably, contours 62 showing the electric field are simulated by a conventional finite element electrostatic modeling software program. As shown in FIG. 5, the widths of traces 4 and 6 and gaps 5 are, preferably, 0.003 inches in length. The ground plane insulating layer 9 separating traces 4 and 6 and ground plane 10 is, preferably, 0.006 inches thick. The surface, insulating layer 8 that covers traces 4 and 6, preferably, is 0.001 inches thick. It is to be understood that with this particular sensor, most of the electric field above traces 4 and 6 is contained in the first 0.003 inches of the media.

FIG. 6 shows a cross-section (similar to the cross-section in FIG. 3) of a portion of a second sensor 20 interacting with media 54 to create contours 62 showing the electric field. The second sensor 20 is constructed in a similar manner as the first sensor 20 (FIG. 5) except that the widths of traces 4 and 6 and gaps 5 are, preferably, 0.010 inches in length.

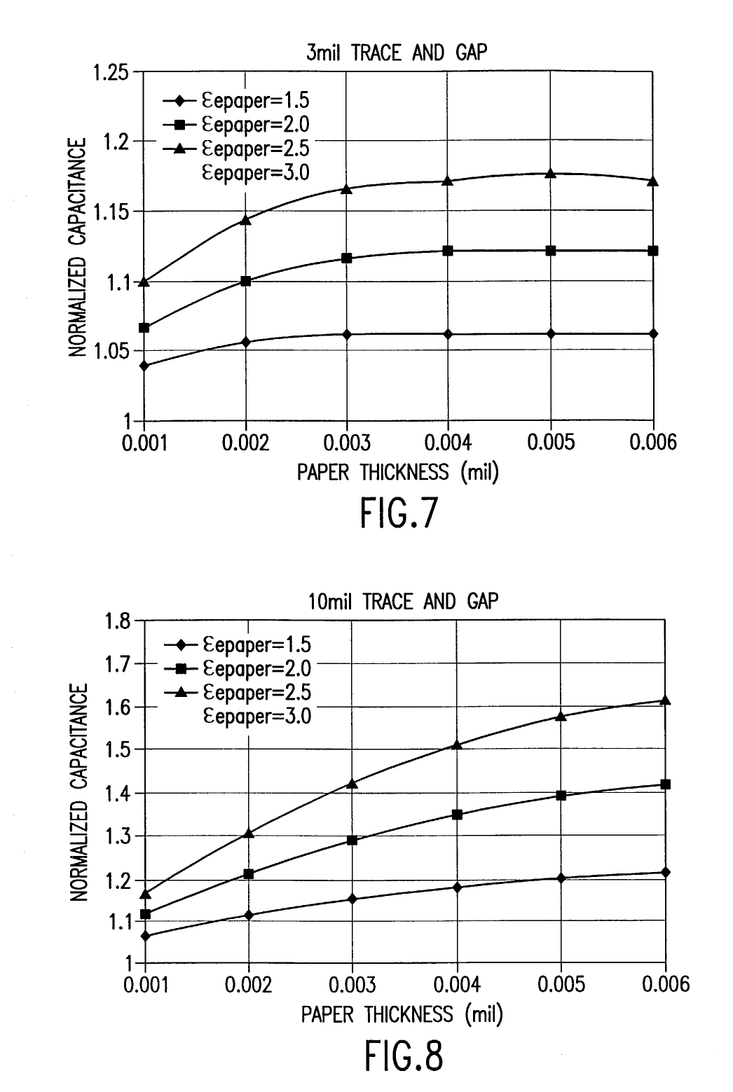

With respect to FIG. 7, the previously discussed conventional finite element electrostatic modeling software program was used to estimate the capacitance between the interleaved traces 4 and 6 as a function of the thickness and the dielectric constant of media 54 placed on sensor 2 or 20. This capacitance value is conventionally normalized to the capacitance of the sensor with no media present. FIG. 7 plots the results of this modeling for the first sensor illustrated in FIG. 5. It is to be understood that paper thickness normally ranges from 0.003 inches to 0.006 inches. The resulting capacitance reading is primarily a function of the dielectric constant of the media and not the thickness of the media.

FIG. 8 plots the results of the conventional finite element electrostatic modeling for the second sensor illustrated in FIG. 6. As can be seen in FIG. 8, with the larger trace and gap widths, the electric field extends through the entire media thickness. The resulting capacitance reading is, therefore, a function of both the dielectric constant and the thickness of the media.

It is to be understood that capacitance ratings from both sensors 2 or 20 can be combined to compute both the dielectric constant and thickness of the media 54, such as paper. In general, each sensor 2 or 20 can be characterized as yielding a capacitance reading that is a function of the thickness and dielectric constant of media 54. The two functions are linearly independent so that they can be solved simultaneously to give a value for the media thickness and dielectric constant. In the media-handling device (not shown) this can be accomplished by generating a two-dimensional look-up table where each combination of two capacitance readings from the sensors is a unique value of the media dielectric constant and thickness.

To further understand the present intention, the first sensor reading would be a function of the dielectric constant only. Knowing the dielectric constant of the media, the media thickness can then be read from the characteristic curves of the second sensor by matching the capacitance from the second sensor to the thickness along a curve of constant dielectric constant.

The first sensor can also be used to sense the volume resistivity of media 54. When media 54 is placed on sensor 2 or 20, the dissipation factor of the resulting capacitor is a function of the volume resistivity of the media 54. The lower the volume resistivity of media 54, the greater is the dissipation factor of the sensor capacitance. The dissipation factor is commonly defined as the ratio of the energy stored in the dielectric per Hz or as the tangent of the loss angle. For dissipation factors less than 0.1, the dissipation factor is approximately equal to the cosine of the phase angle by which the voltage lags the current (the impedance phase angle). This phase angle can then be measured.

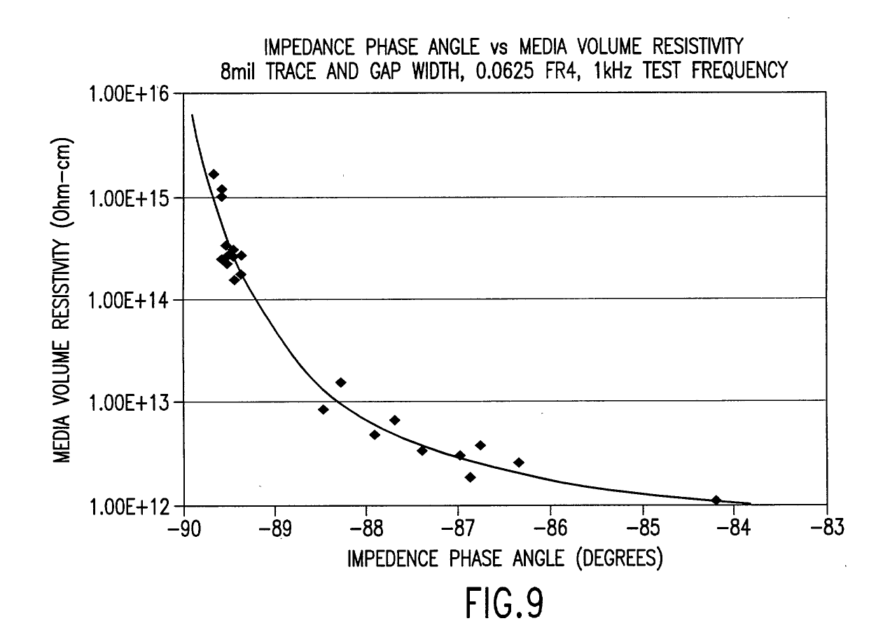

FIG. 9 shows the results of an experiment where a prototype sensor 2 or 20 was used to measure a set of media that also had their volume resistivities conventionally measured with a high resistivity meter and cell. The curve shows the experimental function relating the impedance phase angle to the volume resistivity. By doing a similar test, any of the sensors 2 or 20 can be calibrated so that once the phase angle is measured, the volume resistivity can be estimated. As previously discussed, volume resistivity was very difficult to measure using present DC voltage and current techniques.

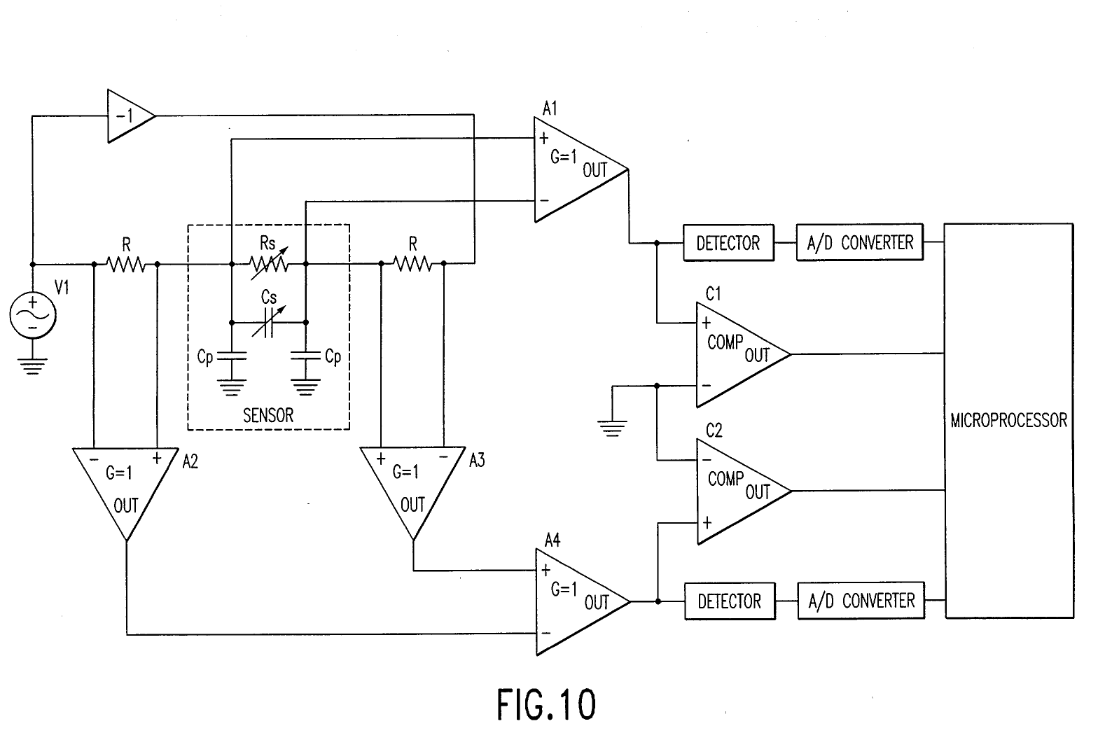

FIG. 10 shows a block diagram of a preferred circuit connected to the first sensor. This sensor can be used to measure the capacitance and the impedance phase angle. An AC voltage is conventionally applied differentially across the sensor through current sense resistors. Differential amplifiers are used to isolate the voltage across the sensor and the voltage across the sense resistors that is proportional to the current through the sensor. The amplitudes of these two AC voltages are measured using a detector circuit consisting of a precision rectifier and an averaging circuit. Comparators turn these two sinusoidal voltages into square waves. The output of detector circuits is connected to a microprocessor using A/D converters. The comparator outputs are connected to digital inputs of the microprocessor. The microprocessor computes the sensor capacitance by taking the ratio of the signal amplitudes. The microprocessor computes the phase angle between the two square waves by timing the delay between them and dividing this delay by the signal period.

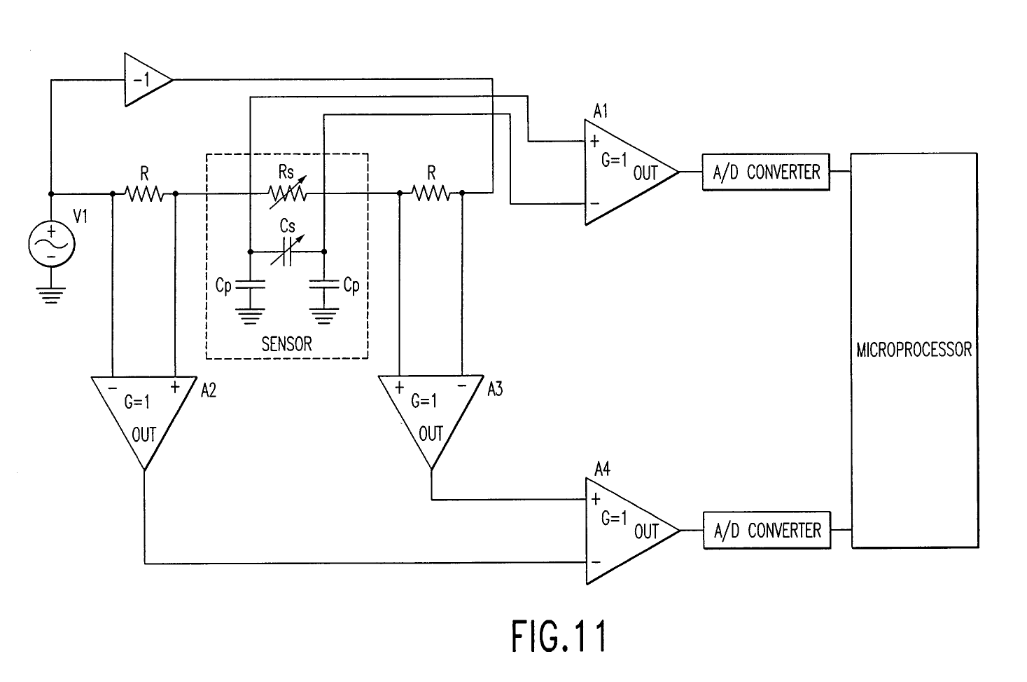

If there is sufficient processing capability in the media handling device microprocessor, FIG. 11 shows how the AC signals representing the sensor voltage and current can be converted to digital signals by A/D converters and the microprocessor and calculate the amplitudes and phase of the signals using conventional digital signal processing (DSP) techniques.

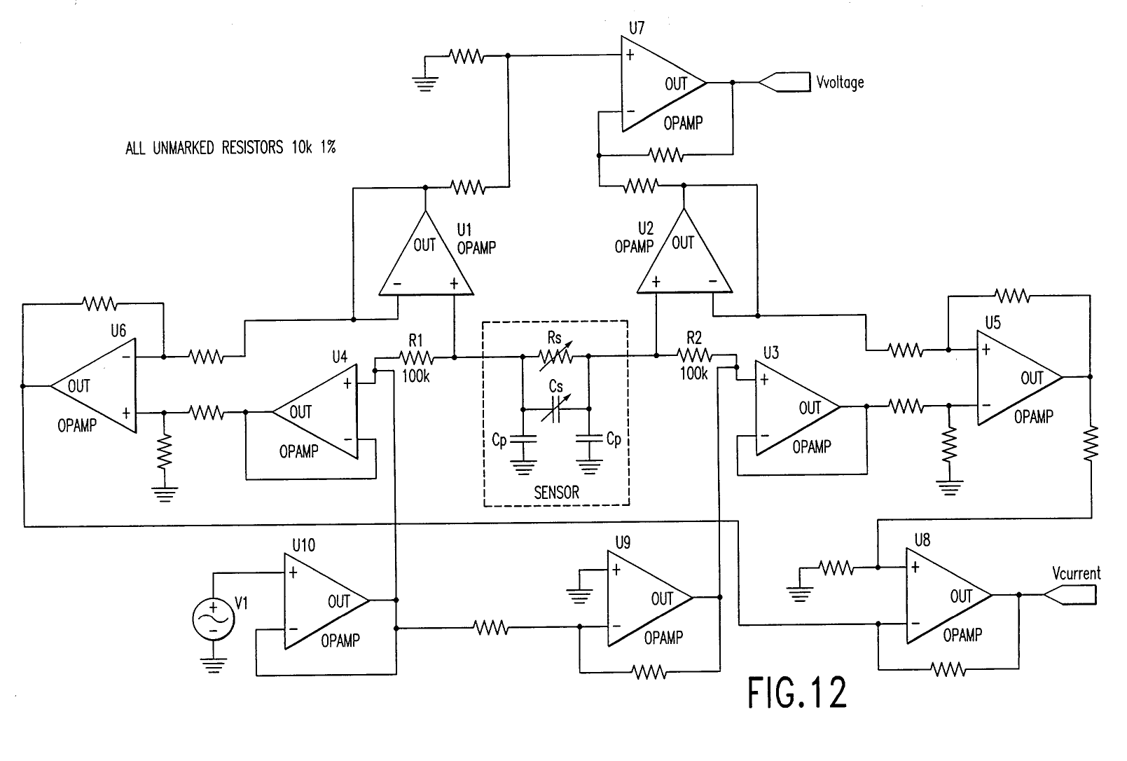

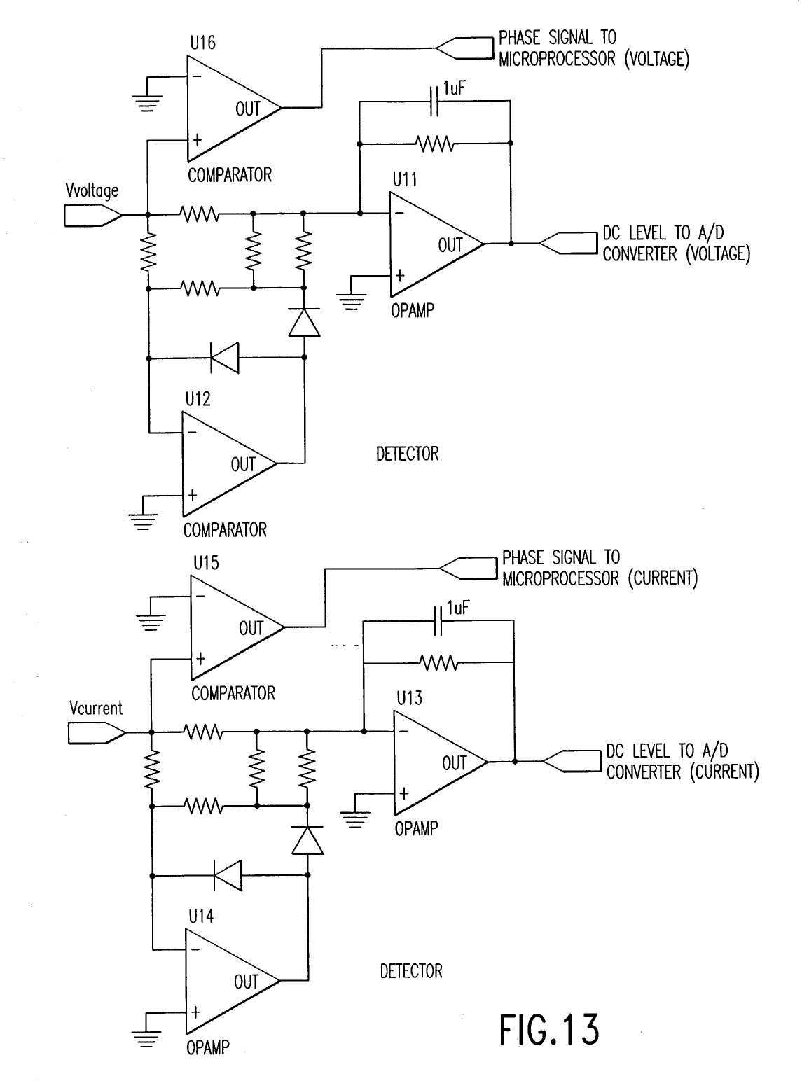

FIGS. 12 and 13 show preferred circuits to implement the block diagrams shown in FIGS. 10 and 11, respectively.

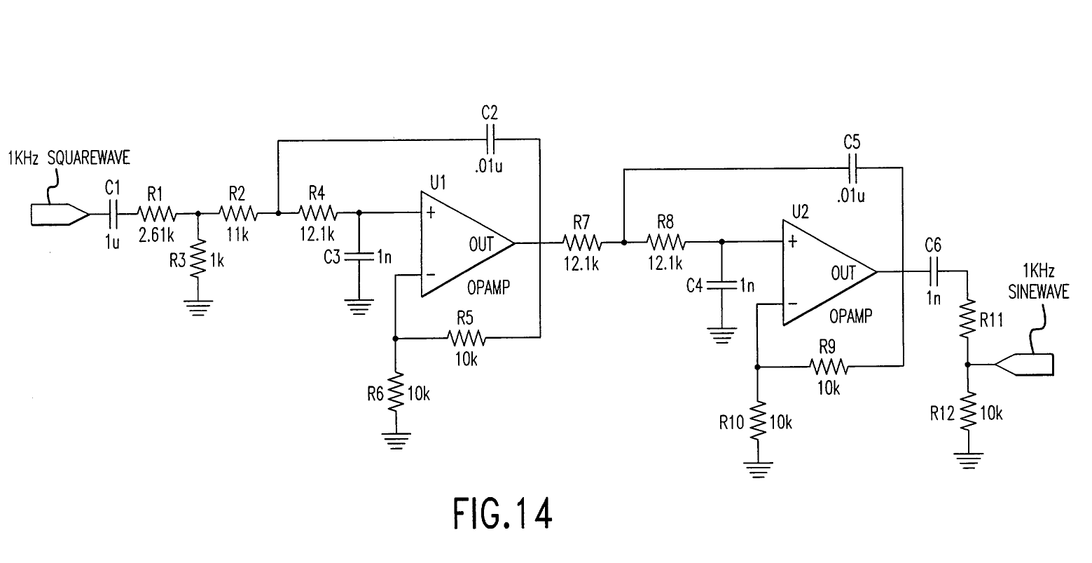

FIG. 14 shows a preferred circuit that can be used to convert a 1 kHz square wave into the sinusoidal signal needed to drive sensor 2 or 20. This 1 kHz square wave could be conventionally generated by an oscillator circuit or it could be conventionally generated by the microprocessor.

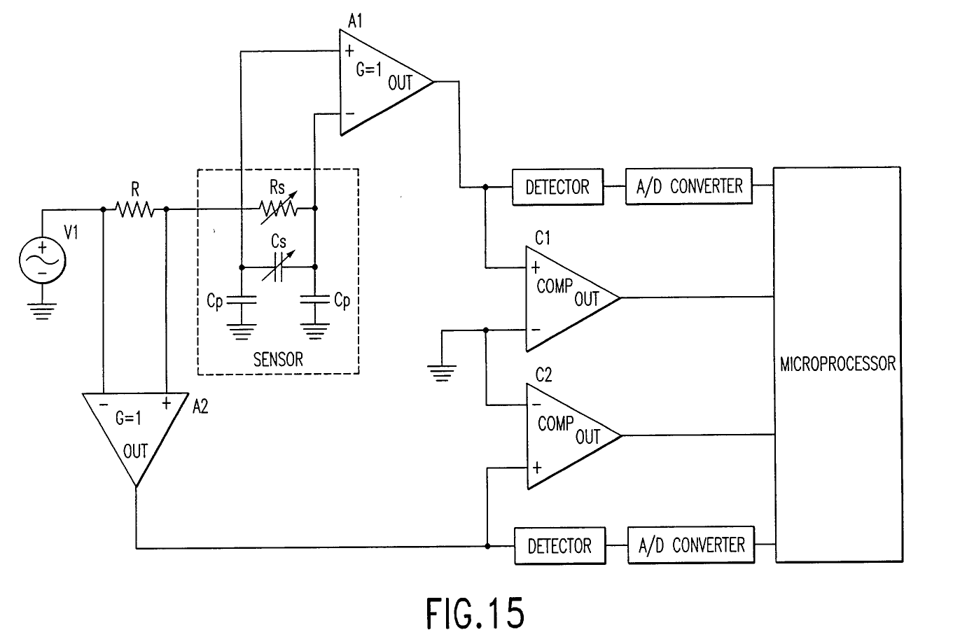

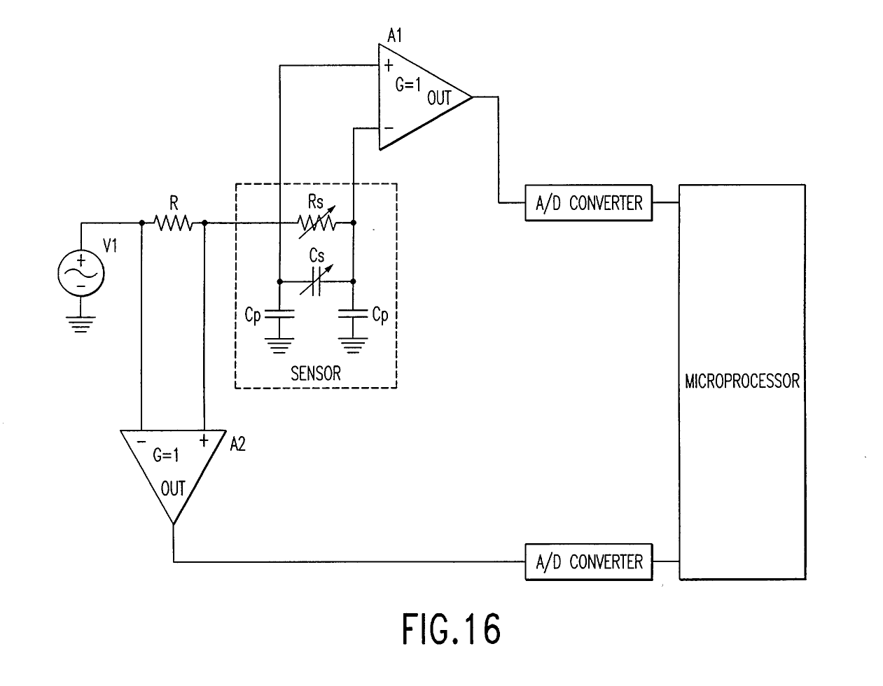

Although the balanced circuit approach shown in FIGS. 10 and 11 may have some inherent noise immunity, it may be possible to make the same measurements using a simpler unbalance approach as shown in block diagrams of FIGS. 15 and 16.

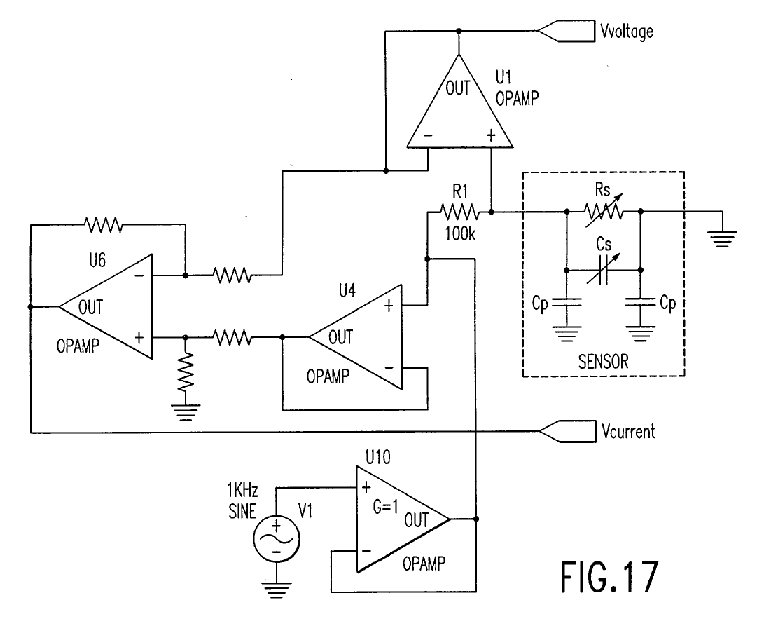

FIG. 17 shows one preferred circuit to implement the balanced approach shown in FIGS. 15 and 16.

The volume resistivity can be estimated using a phase measurement of the first sensor. The second sensor only needs to make a capacitance measurement so that the dielectric constant and the media thickness can be estimated. Although a circuit like that used for the first circuit can be used to make a capacitance measurement with the second sensor, a simpler preferred circuit can be used. The second sensor can be connected to an oscillator circuit whose period is proportional to the sensor capacitance.

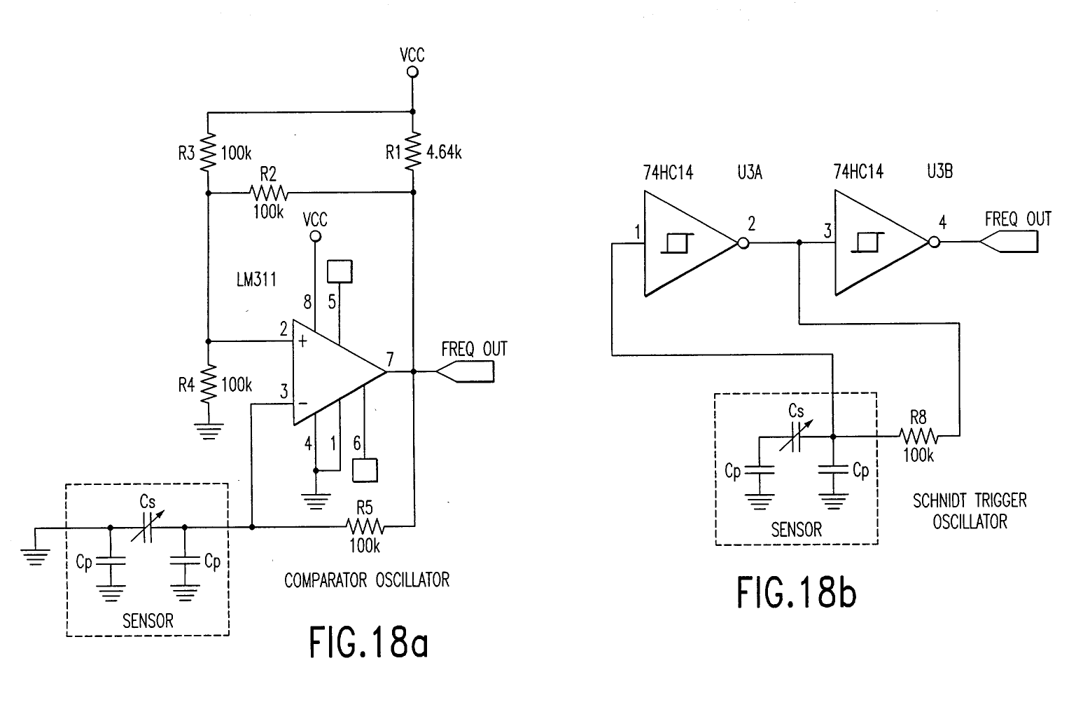

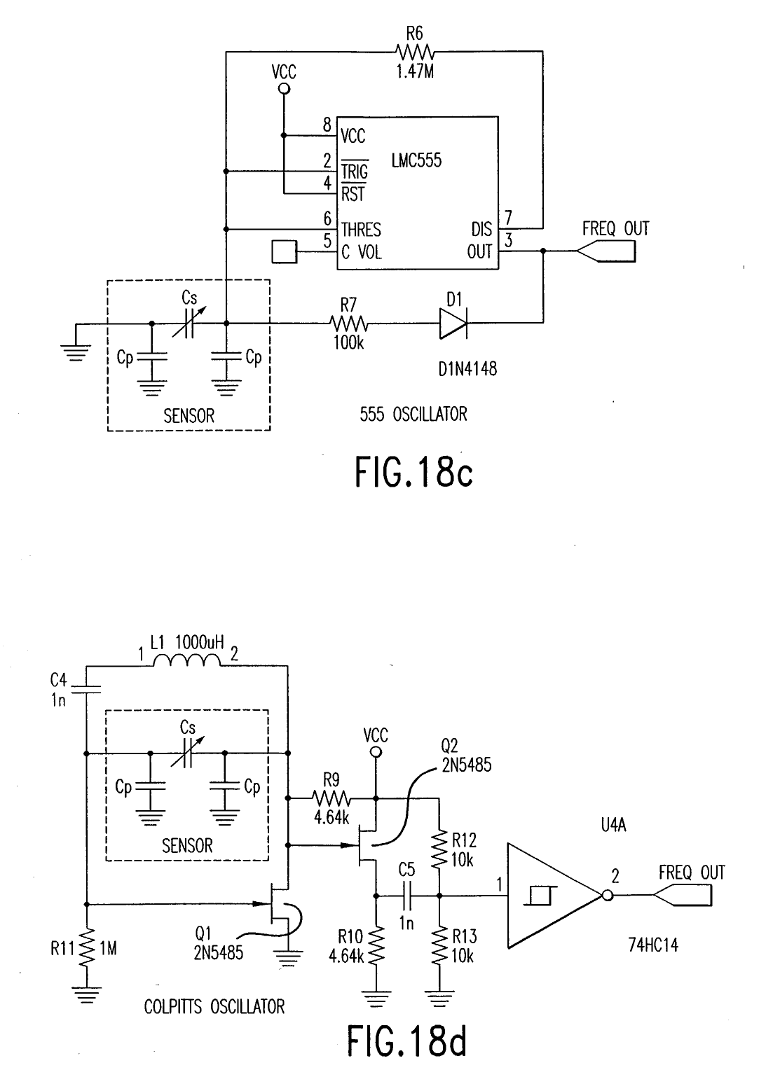

FIGS. 18a-18d illustrate four preferred oscillator circuits. The FREQ OUT signal could be connected to a microprocessor digital input and the microprocessor could be used to measure the oscillator period with and without media 54 on sensor 2 or 20. The microprocessor could then compute the sensor capacitance for the computation of media thickness and dielectric constant.

It is to be understood that the microprocessor that does these calculations could be part of the media handling device control or data formatting electronics. The capacitance of each sensor 2 or 20 would first be measured without media 54 covering sensors 2 or 20. The capacitance measured with media 54 present would be divided by these media-less values to yield normalized capacitance values. The microprocessor could then estimate for media dielectric constant, thickness, and volume resistivity and test the appropriate media handling device process parameters to maximize, for example, the print quality. This estimation could be accomplished by either solving the simultaneous equations approximating the functions represented by the data in FIGS. 7 and 8 or by using a look-up table that is conventionally generated by processing the same data off-line.

Once given the above disclosure, many other features, modifications or improvements will become apparent to the skilled artisan. Such features, modifications or improvements are, therefore, considered to be a part of this invention, the scope of which is to be determined by the following claims.

What is claimed is:

1. A method for measuring/determining the capacitance, dielectric constant and thickness of a media, comprising the steps of:
exposing the one side of a media to a pair of interdigital capacitive sensors;
applying an AC voltage across the sensors;
measuring a capacitance on each of the sensors;
determining a dielectric constant of the media from said capacitance; and
determining a thickness of the media from said capacitance.

2. The method, as in claim 1, wherein said sensors are located substantially adjacent to each other in the same plane.

3. The method, as in claim 1, said dielectric constant and thickness determining steps are further comprised of the steps of:
combining capacitance measurements from each of said sensors; and
computing said dielectric constant and said thickness from said combined capacitance measurements.

4. The method, as in claim 1, wherein said media is further comprised of:
paper.

5. An apparatus for measuring/determining the capacitance, dielectric constant and thickness of the media, comprising:
a plurality of interdigital capacitive sensors;
a surface insulating layer located substantially on one side of said sensors;
a ground plane insulating layer located substantially on the other side of said sensors; and
a ground plane located substantially adjacent to said ground plane insulating layer.

6. The apparatus, as in claim 5, wherein said sensors are further comprised of:
a plurality of traces; and
a plurality of gaps located substantially between said traces.

7. The apparatus, as in claim 6, wherein a first sensor is further comprised of:
a width of said traces and gaps being approximately 0.003 inches.

8. The apparatus, as in claim 6, wherein a second sensor is further comprised of:
a width of said traces and gaps being approximately 0.010 inches.

9. The apparatus, as in claim 5, wherein said surface insulating layer is further comprised of:
polyimide.

10. The apparatus, as in claim 5, wherein said ground plane insulating layer is further comprised of:
polyimide.

11. The apparatus, as in claim 5, wherein said media is further comprised of:
paper.

12. The apparatus, as in claim 5, wherein said sensors are located substantially adjacent to each other in the same plane.

13. A program storage medium readable by a computer, tangibly embodying a program of instructions executable by the computer to perform method steps for a method for measuring/determining the capacitance, dielectric constant and thickness of a media, comprising the steps of:
exposing the one side of a media to a pair of interdigital capacitive sensors;
applying an AC voltage across the sensors;
measuring a capacitance on each of the sensors;
determining a dielectric constant of the media from said capacitance; and
determining a thickness of the media from said capacitance.

14. The method, as in claim 13, wherein said sensors are located substantially adjacent to each other in the same plane.

15. The method, as in claim 13, said dielectric constant and thickness determining steps are further comprised of the steps of:
combining capacitance measurements from each of said sensors; and
computing said dielectric constant and said thickness from said combined capacitance measurements.

16. The method, as in claim 13, wherein said media is further comprised of:
paper.
